(19) United States
(12) Patent Application Publication
(10) Pub. No.: US 2025/0254888 A1
(43) Pub. Date: Aug. 7, 2025

(54) MRAM DEVICE WITH MULTIPLE PART BOTTOM ELECTRODE

(71) Applicant: INTERNATIONAL BUSINESS MACHINES CORPORATION, ARMONK, NY (US)

(72) Inventors: Oscar van der Straten, Guilderland Center, NY (US); Linda W Wangoh, Cohoes, NY (US); Chih-Chao Yang, Glenmont, NY (US)

(21) Appl. No.: 18/433,512

(22) Filed: Feb. 6, 2024

(51) Int. Cl. H10B 61/00; G01R 33/09; H10N 50/10; H10N 50/80

(52) U.S. Cl. CPC H10B 61/20; G01R 33/098; H10N 50/10; H10N 50/80

(57) ABSTRACT

A semiconductor device including a magnetic tunnel junction (MTJ) stack having a bottom electrode, where the bottom electrode includes a first bottom electrode pad and a bottom electrode pillar. A MTJ stack including vertically aligned layers of a top electrode, a free layer, a tunneling barrier, a reference layer and a bottom electrode, where the top electrode includes a tapered side surface having a width at an upper surface of the top electrode greater than a width at a lower surface of the top electrode, and the bottom electrode includes a first bottom electrode pad and a bottom electrode pillar. A MTJ stack, the MTJ stack having a bottom electrode, where the bottom electrode includes a bottom electrode pillar on a first bottom electrode pad on a second bottom electrode pad on a third bottom electrode pad.

### BACKGROUND

The present invention relates, generally, to the field of semiconductor manufacturing, and more particularly to fabricating a magnetic tunnel junction device with a multiple part bottom electrode.

Magneto resistive random-access memory (“MRAM”) devices are used as non-volatile computer memory. MRAM data is stored by magnetic storage elements. The elements are formed from two ferromagnetic layers, each of which can hold a magnetic field, separated by a spin conductor layer. One of the two layers is a reference magnet, or a reference layer, set to a particular polarity, while the remaining layer's field can be changed to match an external field to store memory and is termed the “free magnet” or “free-layer”. This configuration is known as the magnetic tunnel junction (MTJ) and is the simplest structure for a MRAM bit of memory.

### SUMMARY

According to an embodiment of the present invention, a semiconductor device is provided. The semiconductor device including a magnetic tunnel junction (MTJ) stack having a bottom electrode, where the bottom electrode includes a first bottom electrode pad and a bottom electrode pillar.

According to an embodiment of the present invention, a magnetic tunnel junction stack is provided, the magnetic junction stack including vertically aligned layers of a top electrode, a free layer, a tunneling barrier, a reference layer and a bottom electrode, where the top electrode includes a tapered side surface having a width at an upper surface of the top electrode greater than a width at a lower surface of the top electrode, and the bottom electrode includes a first bottom electrode pad and a bottom electrode pillar.

According to an embodiment of the present invention, a semiconductor device is provided. The semiconductor device including a magnetic tunnel junction (MTJ) stack having a bottom electrode, where the bottom electrode includes a bottom electrode pillar on a first bottom electrode pad on a second bottom electrode pad on a third bottom electrode pad, wherein the first bottom electrode pad has a first width smaller than a second width of the second bottom electrode pad, which is smaller than a third width of the third bottom electrode pad, where the first bottom electrode pad has the first width greater than a first height of the first bottom electrode pad, the second bottom electrode pad has the second width greater than a second height of the second bottom electrode pad, the third bottom electrode pad has the third width greater than a third height of the third bottom electrode pad, and the bottom electrode pillar has a fourth height greater than a fourth width of the bottom electrode pillar, wherein the MTJ stack includes a top electrode above a free layer, the free layer above a tunneling barrier, the tunneling barrier above a reference layer, the reference layer above the bottom electrode pillar, where the top electrode, the free layer, the tunneling barrier and the reference layer each include a tapered side surface of the same angle, where the top electrode, the free layer, the tunneling barrier and the reference layer each include a width at an upper surface greater than a width at a lower surface.

### BRIEF DESCRIPTION OF THE DRAWINGS

The following detailed description, given by way of example and not intended to limit the invention solely thereto, will best be appreciated in conjunction with the accompanying drawings, in which:

FIG. 1 illustrates a cross-sectional view of a multi-state memory cell, according to an exemplary embodiment;

FIG. 2 illustrates a cross-sectional view of the multi-state memory cell and illustrates formation of a bottom electrode pad, according to an exemplary embodiment;

FIG. 3 illustrates a cross-sectional view of the multi-state memory cell and illustrates formation of an inter-layer dielectric and a hard mask, according to an exemplary embodiment;

FIG. 4 illustrates a cross-sectional view of the multi-state memory cell and illustrates patterning of the inter-layer dielectric and removal of the hard mask, according to an exemplary embodiment;

FIG. 5 illustrates a cross-sectional view of the multi-state memory cell and illustrates formation of a first encapsulation layer, according to an exemplary embodiment;

FIG. 6 illustrates a cross-sectional view of the multi-state memory cell and illustrates removal of portions of the first encapsulation layer, according to an exemplary embodiment;

FIG. 7 illustrates a cross-sectional view of the multi-state memory cell and illustrates formation of a bottom electrode, according to an exemplary embodiment;

FIG. 8 illustrates a cross-sectional view of the multi-state memory cell and illustrates formation of another inter-layer dielectric and a hard mask, according to an exemplary embodiment;

FIG. 9 illustrates a cross-sectional view of the multi-state memory cell and illustrates patterning of the another inter-layer dielectric and removal of the hard mask, according to an exemplary embodiment;

FIG. 10 illustrates a cross-sectional view of the multi-state memory cell and illustrates formation of a second encapsulation layer, according to an exemplary embodiment;

FIG. 11 illustrates a cross-sectional view of the multi-state memory cell and illustrates formation of a reference layer, according to an exemplary embodiment;

FIG. 12 illustrates a cross-sectional view of the multi-state memory cell and illustrates formation of another inter-layer dielectric and a hard mask, according to an exemplary embodiment;

FIG. 13 illustrates a cross-sectional view of the multi-state memory cell and illustrates patterning of the another inter-layer dielectric and removal of the hard mask, according to an exemplary embodiment;

FIG. 14 illustrates a cross-sectional view of the multi-state memory cell and illustrates formation of a third encapsulation layer, according to an exemplary embodiment;

FIG. 15 illustrates a cross-sectional view of the multi-state memory cell and illustrates formation of a tunneling barrier, according to an exemplary embodiment;

FIG. 16 illustrates a cross-sectional view of the multi-state memory cell and illustrates formation of another inter-layer dielectric and a hard mask, according to an exemplary embodiment;

FIG. 17 illustrates a cross-sectional view of the multi-state memory cell and illustrates patterning of the another inter-layer dielectric and removal of the hard mask and formation of a fourth encapsulation layer, according to an exemplary embodiment;

FIG. 18 illustrates a cross-sectional view of the multi-state memory cell and illustrates formation of a free layer, according to an exemplary embodiment;

FIG. 19 illustrates a cross-sectional view of the multi-state memory cell and illustrates patterning of another inter-layer dielectric and removal of the hard mask and formation of a fifth encapsulation layer and a top electrode, according to an exemplary embodiment;

FIG. 20 illustrates a cross-sectional view of the multi-state memory cell and illustrates formation of an upper metal wire, according to an exemplary embodiment; and

FIG. 21 illustrates a cross-sectional view of a multi-state memory cell, according to an exemplary embodiment.

The drawings are not necessarily to scale. The drawings are merely schematic representations, not intended to portray specific parameters of the invention. The drawings are intended to depict only typical embodiments of the invention. In the drawings, like numbering represents like elements.

### DETAILED DESCRIPTION

Detailed embodiments of the claimed structures and methods are disclosed herein; however, it can be understood that the disclosed embodiments are merely illustrative of the claimed structures and methods that may be embodied in various forms. This invention may, however, be embodied in many different forms and should not be construed as limited to the exemplary embodiment set forth herein. Rather, these exemplary embodiments are provided so that this disclosure will be thorough and complete and will fully convey the scope of this invention to those skilled in the art. In the description, details of well-known features and techniques may be omitted to avoid unnecessarily obscuring the presented embodiments.

For purposes of the description hereinafter, the terms “upper”, “lower”, “right”, “left”, “vertical”, “horizontal”, “top”, “bottom”, and derivatives thereof shall relate to the disclosed structures and methods, as oriented in the drawing figures. The terms “overlying”, “atop”, “on top”, “positioned on” or “positioned atop” mean that a first element, such as a first structure, is present on a second element, such as a second structure, wherein intervening elements, such as an interface structure may be present between the first element and the second element. The term “direct contact” means that a first element, such as a first structure, and a second element, such as a second structure, are connected without any intermediary conducting, insulating or semiconductor layers at the interface of the two elements.

In the interest of not obscuring the presentation of embodiments of the present invention, in the following detailed description, some processing steps or operations that are known in the art may have been combined together for presentation and for illustration purposes and in some instances may have not been described in detail. In other instances, some processing steps or operations that are known in the art may not be described at all. It should be understood that the following description is rather focused on the distinctive features or elements of various embodiments of the present invention.

As stated above, magneto resistive random-access memory (hereinafter “MRAM”) devices are a non-volatile computer memory technology. MRAM data is stored by magnetic storage elements. The elements are formed from two ferromagnetic layers, each of which can hold a magnetic field, separated by a spin conductor layer. One of the two layers is a reference magnet, or a reference layer, set to a particular polarity, while the remaining layer's field can be changed to match that of an external field to store memory and is termed the “free magnet” or “free-layer”. The magnetic reference layer may be referred to as a reference layer, and the remaining layer may be referred to as a free layer. This configuration is known as the magnetic tunnel junction (hereinafter “MTJ”) and is the simplest structure for a MRAM bit of memory.

A memory device is built from a grid of such memory cells or bits. In some configurations of MRAM, such as the type further discussed herein, the magnetization of the magnetic reference layer is fixed in one direction (up or down), and the direction of the magnetic free layer can be switched by external forces, such as an external magnetic field or a spin-transfer torque generating charge current. A smaller current (of either polarity) can be used to read resistance of the device, which depends on relative orientations of the magnetizations of the magnetic free layer and the magnetic reference layer. The resistance is typically higher which the magnetizations are anti-parallel and lower when they are parallel, though this can be reversed, depending on materials used in fabrication of the MRAM.

The MRAM stack layers may be conformally formed using known techniques. In formation of the MTJ stacks layers, the reference layer is formed on a dielectric and a bottom electrode. The tunneling barrier layer is formed on the reference layer. In an embodiment, the tunneling barrier layer is a barrier, such as a thin insulating layer or electric potential, between two electrically conducting materials. Electrons (or quasiparticles) pass through the tunneling barrier layer by the process of quantum tunneling. In certain embodiments, the tunneling barrier layer includes at least one sublayer composed of magnesium oxide (MgO). It should be appreciated that materials other than MgO can be used to form the tunneling barrier layer. The free layer is a magnetic free layer that is adjacent to tunneling barrier layer and opposite the reference layer. The free layer has a magnetic moment or magnetization that can be flipped. It should also be appreciated that the MTJ stack layers may include additional layers, omit certain layers, and each of the layers may include any number of sublayers. Moreover, the composition of layers and/or sublayers may be different between the different MRAM stacks.

For high performance MRAM devices based on perpendicular magnetic tunnel junction (MTJ) structures, well-defined interfaces and interface control are essential. MTJ structures typically include a cobalt (Co) based synthetic anti-ferromagnet (SAF), a CoFeB-based reference layer, a MgO-based tunnel barrier, a CoFeB-based free layer, and cap layers containing e.g. tantalum (Ta) and/or ruthenium (Ru). Embedded MTJ structures are usually formed by subtractive patterning of blanket MTJ stacks into pillars between two metal levels. After MTJ stack patterning, the inter-pillar spaces are filled with ILD to enable connection to upper level wiring by a top contact of the MTJ structure. Forming of an inter-layer dielectric (hereinafter “ILD”) gapfill between pillars presents a significant challenge as the presence of voids in the ILD between the pillars can lead to shorts. MTJ structures are typically formed between metal lines or metal wiring and has a defined height. The MTJ structure layers of the free layer, the tunneling barrier and the reference layer are sandwiched between a top electrode and a bottom electrode of the MTJ stack.

In this invention, after each layer of MTJ stack patterning, inter-pillar spaces are filled with an inter-layer dielectric (hereinafter “ILD”) to enable connection to between lower level wiring and upper level wiring without voids in the ILD, due to lower thickness or height of each of the individual ILD surrounding each layer of the MTJ stack and lower risk of voids.

In this invention, variations of a multi-level bottom electrode are used to enable connection between the lower level wiring and the upper level wiring by a top contact without voids in the ILD. One or more bottom electrode pads are first formed on the lower metal wiring. After each layer of formation of the one or more bottom electrode pads, inter-pillar spaces are filled with an ILD. A bottom electrode pillar is formed on the one or more bottom electrode pads, and inter-pillar spaces are filled with an ILD. Each of the one or more bottom electrode pads have a width that is greater than a height. The bottom electrode pillar has a height which is greater than a width.

In this invention, the MTJ stack layers of the reference layer, the tunneling barrier, the free layer and the top electrode have an outwardly tapered vertical side surface, when moving from a lower surface to an upper surface of the MTJ device, from the lower metal wire to the upper metal wire. Forming the outwardly tapered vertical side surface side profile of the MTJ device helps to reduce gaps in the ILD surrounding the devices as separately formed ILDs, each for a lower height than forming a single ILD, surround an entire vertical side surface of the MTJ device. Additionally, when forming each layer of the ILD, an upper surface of the ILD has a smaller area than a lower of the ILD, helping to reduce formation of voids. The MTJ device with individually formed layers improved MRAM performance due to reduced shorts between top contacts of adjacent MTJ device pillars.

An MRAM pillar with a multi-level bottom electrode helps to reduce ILD voiding between adjacent MTJ stacks. This helps to extend scalability of MRAM device memory elements due to void-free gap fill between MRAM pillars and improved embedded MRAM performance due to reduced top contact shorts.

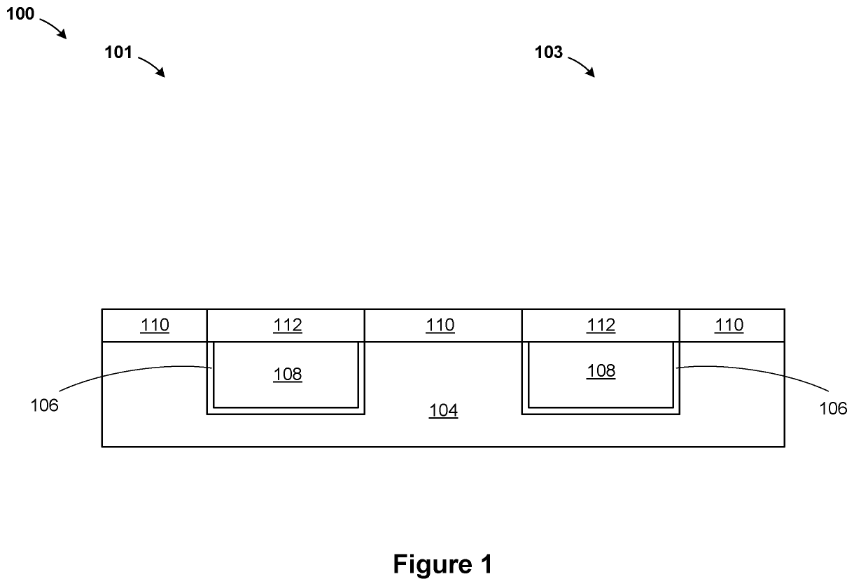

Referring now to FIG. 1, a semiconductor structure 100 (hereinafter “structure”) at an intermediate stage of fabrication is shown according to an exemplary embodiment. FIG. 1 is a cross-sectional view of the structure 100. The structure 100 may be formed or provided. The structure 100 may include a cell 101 and a cell 103. The cells 101, 103, each include, for example, an inter-layer dielectric (hereinafter “ILD”) 104, a liner 106, a lower metal wire 108, a dielectric cap 110, and a metal cap 112.

The structure 100 may include several back end of line (“BEOL”) layers. In general, the back end of line (BEOL) is the second portion of integrated circuit fabrication where the individual devices (transistors, capacitors, resistors, etc.) are interconnected with wiring on the wafer.

The ILD 104 may be formed by depositing or growing a dielectric material on the BEOL layers, followed by a chemical mechanical polishing (CMP) or etch steps. The ILD 104 may be deposited using typical deposition techniques, for example, chemical vapor deposition (CVD), plasma enhanced chemical vapor deposition (PECVD), atomic layer deposition (ALD), molecular layer deposition (MLD), physical vapor deposition (PVD), high density plasma (HDP) deposition, and spin on techniques, followed by a planarization process, such as CMP, or any suitable etch process. In an embodiment, the ILD 104 may include one or more layers. In an embodiment, the ILD 104 may include any dielectric material such as organosilicate glass (SiCOH), silicon carbide oxynitride (SiCNO), silicon carbide oxynitride hydride (SiCHNO), silicon oxide (SiOx), silicon nitride (SiNx), silicon boron carbonitride (SiBCN), a low-k dielectric material (with k<4.0), including but not limited to, silicon oxide, spin-on-glass, a flowable oxide, a high-density plasma oxide, borophosphosilicate glass (BPSG), or any combination thereof or any other suitable dielectric material. A specific dielectric material from those dielectric materials listed above may be chosen for ILD 104 depending on a desired capacitance.

The lower metal wire 108 may be formed by first patterning two or more trenches (not shown) into the ILD 104, lining the two or more trenches with the liner 106, and filling the two or more trenches.

The liner 106 separates the conductive interconnect material of the lower metal wire 108 from the ILD 104. The liner 106 may be composed of, for example, tantalum nitride (TaN), tantalum (Ta), titanium (Ti), titanium nitride (TiN), or a combination thereof. The liner 106 may be deposited utilizing a conventional deposition process such as, for example, CVD, plasma enhanced chemical vapor deposition (PECVD), PVD or ALD. The liner 106 may be 5 nm thick, although a thickness less than or greater than 5 nm may be acceptable. The liner 106 surrounds a lower horizontal surface and a vertical side surface of the lower metal wire 108.

In an embodiment, the lower metal wire 108 is formed from a conductive material layer which is blanket deposited on top of the structure 100, and directly on a top surface of the liner 106, filling the two or more trenches (not shown). The conductive material layer may include materials such as, for example copper (Cu), ruthenium (Ru), cobalt (Co), tungsten (W). The conductive material can be formed by for example, chemical vapor deposition (CVD), physical vapor deposition (PVD), and atomic layer deposition (ALD) or a combination thereof. The lower metal wire 108 is formed by damascene, or patterned from the conductive material layer, using known patterning and etching techniques. There may be any number of openings in the ILD 104, each filled with the liner 106 and the lower metal wire 108, on the structure 100.

A planarization process, such as, for example, chemical mechanical polishing (CMP), may be done to remove excess material from a top surface of the structure 100 such that upper horizontal surfaces of the lower metal wire 108, the liner 106 and the ILD 104 are coplanar.

In an embodiment, the lower metal wire 108 may have a thickness ranging from about 10 nm to about 100 nm, although a thickness less than 10 nm and greater than 100 nm may be acceptable.

The dielectric cap 110 may be formed as described for the ILD 104, directly on a top surface of the liner 106, the lower metal wire 108 and the ILD 104. The metal cap 112 may be formed by first patterning two or more second trenches (not shown) into the dielectric cap 110 vertically aligned above the lower metal wire 108 and the liner 106, and filling the two or more second trenches. The dielectric cap 110 is unlikely to contain voids as the dielectric cap 110 is blanket deposited on the planarized upper surface of the lower metal wire 108 and the liner 106.

In an embodiment, the metal cap 112 is formed from a conductive material layer which is blanket deposited on top of the structure 100, and directly on a top surface of the dielectric cap 110, the liner 106, the lower metal wire 108 and the ILD 104. The conductive material layer may include materials such as, for example tantalum (Ta), ruthenium (Ru), titanium (Ti), tungsten (W). The conductive material can be formed by for example, chemical vapor deposition (CVD), physical vapor deposition (PVD), and atomic layer deposition (ALD) or a combination thereof. The metal cap 112 is formed by damascene, or patterned from the conductive material layer, using known patterning and etching techniques. Damascene is the method of BEOL interconnect formation. A dielectric is deposited, patterned, and the resulting feature is metallized. Any metal overburden is removed by planarization.

A planarization process, such as, for example, chemical mechanical polishing (CMP), may be done to remove excess material from a top surface of the structure 100 such that upper horizontal surfaces of the metal cap 112 and the dielectric cap 110 are coplanar.

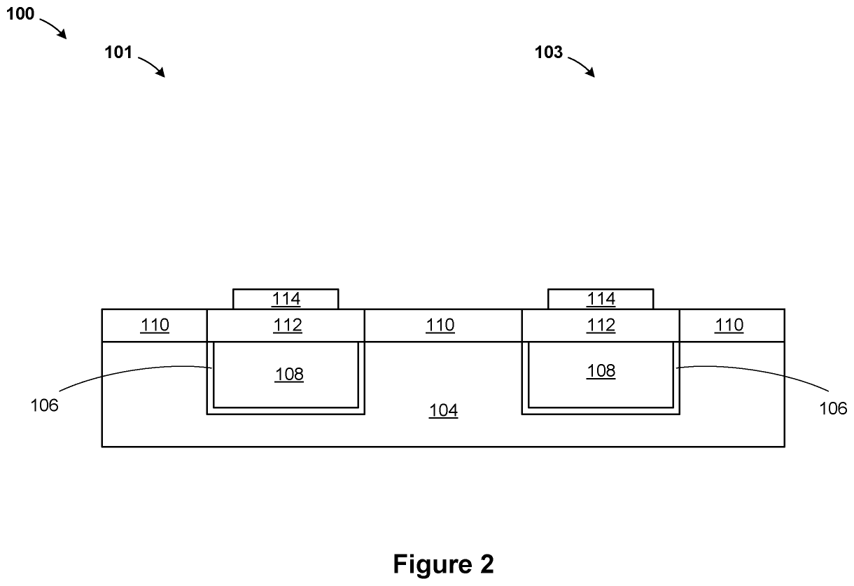

Referring now to FIG. 2, a cross-sectional view of the structure 100 is shown, according to an embodiment. A bottom electrode pad 114 may be formed.

In an embodiment, the bottom electrode pad 114 is formed from a conductive material layer which is blanket deposited on top of the structure 100, and directly on a top surface of the dielectric cap 110 and the metal cap 112. The conductive material layer may include materials such as, for example tungsten nitride (WN), titanium nitride (TiN) tantalum (Ta), ruthenium (Ru), titanium (Ti), tungsten (W), molybdenum (Mo), platinum (Pt). The conductive material can be formed by for example, chemical vapor deposition (CVD), physical vapor deposition (PVD), and atomic layer deposition (ALD) or a combination thereof. The bottom electrode pad 114 is patterned from the conductive material layer, using known patterning and etching techniques. Depending on a desired bottom electrode resistance, a specific metallic material from those metallic materials listed above may be chosen for bottom electrode pad 114.

The bottom electrode pad 114 is vertically aligned with the metal cap 112 and the lower metal wire 108 in each of the cells 101, 103. The bottom electrode pad 114 has a width which is greater than a height.

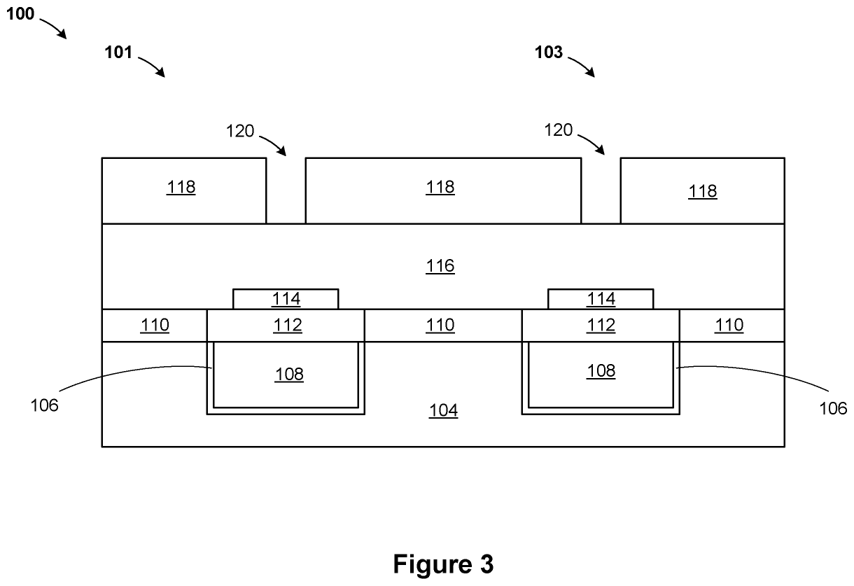

Referring now to FIG. 3, a cross-sectional view of the structure 100 is shown, according to an embodiment. An inter-layer dielectric (hereinafter “ILD”) 116 and a hard mask 118 may be formed.

The ILD 116 may be formed as described for the ILD 104, directly on vertical side surfaces of the bottom electrode pad 114 and on upper horizontal surfaces of the bottom electrode pad 114, the metal cap 112 and the dielectric cap 110. The ILD 116 is unlikely to contain voids as the ILD 116 is blanket deposited on the planarized upper surface of the metal cap 112 and the dielectric cap 110 and the upper and side surfaces of the bottom electrode pad 114.

A planarization process, such as, for example, chemical mechanical polishing (CMP), may be done to remove excess material from a top surface of the structure 100 such that an upper horizontal surface of the ILD 116 is planar.

The hard mask 118 is formed on the structure 100 and patterned, directly on an upper horizontal surface of the ILD 116. The hard mask 118 may be patterned such that portions of the hard mask 118 are removed, forming an opening 120. The opening 120 may be vertical aligned above the bottom electrode pad 114, the metal cap 112 and the lower metal wire 108, in each of the cells 101, 103.

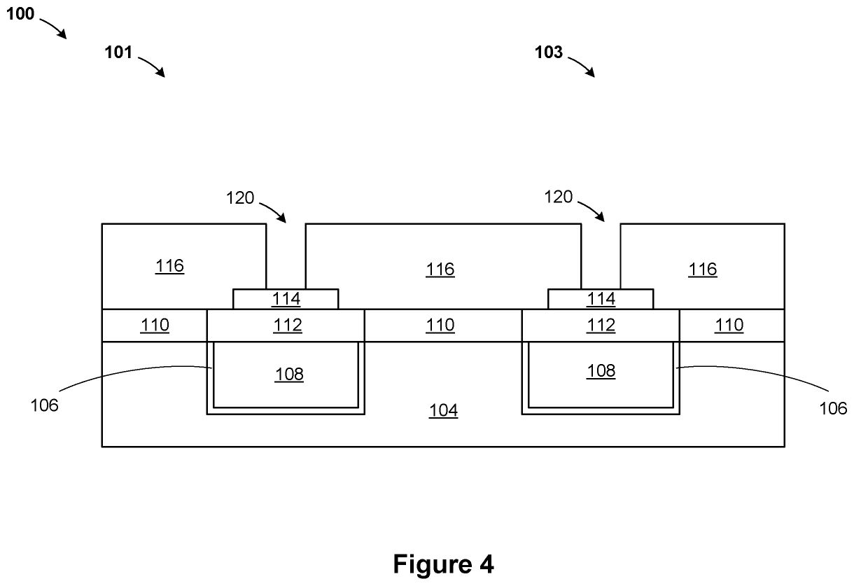

Referring now to FIG. 4, a cross-sectional view of the structure 100 is shown, according to an embodiment. Portions of the ILD 116 may be removed. The hard mask 118 may be removed.

The portions of the ILD 116 may be removed exposing an upper surface of the bottom electrode pad 114. The portions of the ILD 116 may be selectively removed using an anisotropic etching technique, such as, for example, reactive ion etching, extending the openings 120.

The hard mask 118 may be removed using known techniques.

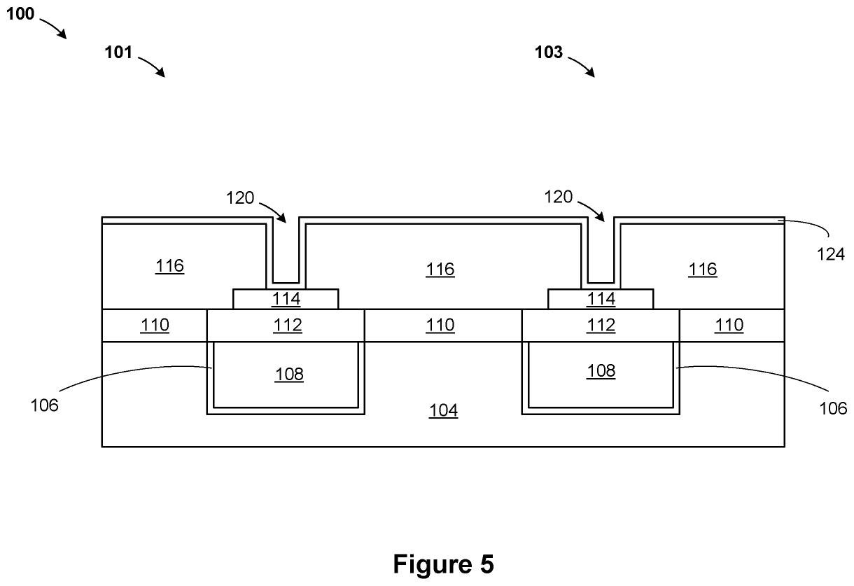

Referring now to FIG. 5, a cross-sectional view of the structure 100 is shown, according to an embodiment. A first encapsulation layer 124 may be formed.

The first encapsulation layer 124 may be conformally formed on the structure 100, on an upper horizontal surface of the ILD 116, and on an upper horizontal surface of the bottom electrode pad 114, filling a portion of the opening 120. The first encapsulation layer 124 may include materials such as, for example, any dielectric material such as hafnium oxide (HfO₂), aluminum oxide (Al₂O₃), silicon nitride (SiN) and silicon nitride carbon (SiNC) and may include a single layer or may include multiple layers of dielectric material. In an alternate embodiment, the first encapsulation layer 124 may include zirconium oxide (ZrO₂). The first encapsulation layer 124 may be deposited using typical deposition techniques, for example, physical vapor deposition, atomic layer deposition, molecular layer deposition, and chemical vapor deposition. The first encapsulation layer 124 may have a thickness between 3 nm and 30 nm, although thickness greater than 30 nm or less than 3 nm are acceptable. A specific dielectric encapsulation material from those dielectric encapsulation materials listed above may be chosen for first encapsulation layer 124 depending on a bottom electrode metallic material used.

The first encapsulation layer 124 helps to protect a subsequently formed bottom electrode from being damaged or oxidized during subsequent ILD materials deposition.

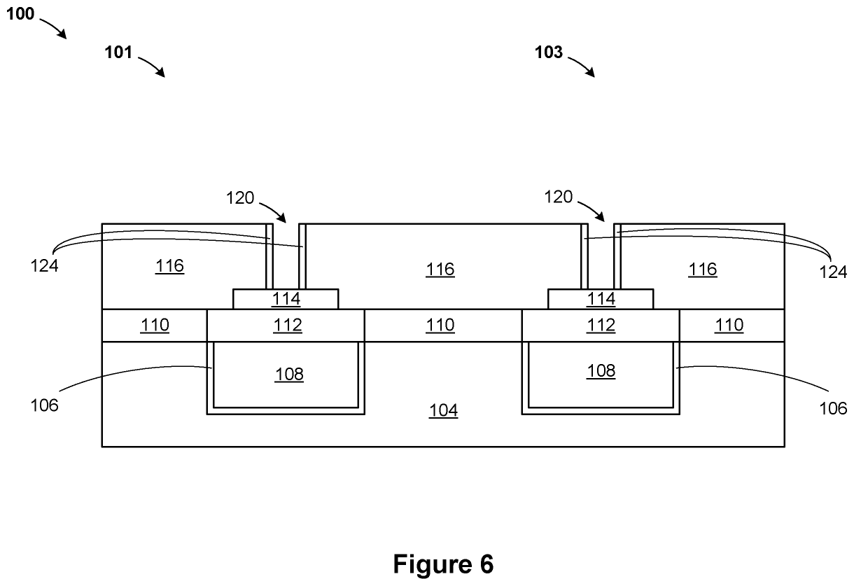

Referring now to FIG. 6, a cross-sectional view of the structure 100 is shown, according to an embodiment. Portions of first encapsulation layer 124 may be removed.

The portions of the first encapsulation layer 124 may be selectively removed using an anisotropic etching technique, such as, for example, reactive ion etching. The remaining portions of the first encapsulation layer 124 may remain vertically aligned directly adjacent to the ILD 116, in both the cells 101, 103. The first encapsulation layer 124 may be removed from upper horizontal surfaces of the bottom electrode pad 114 and the ILD 116.

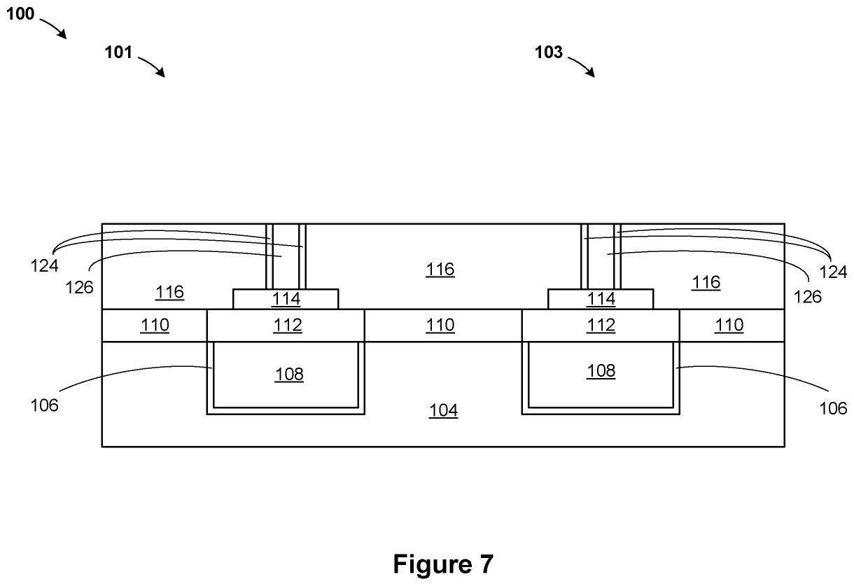

Referring now to FIG. 7, a cross-sectional view of the structure 100 is shown, according to an embodiment. A bottom electrode pillar 126 may be formed.

In an embodiment, the bottom electrode pillar 126 is formed from a conductive material layer which is blanket deposited on top of the structure 100, and directly on an upper surface of the bottom electrode pad 114, the first encapsulation layer 124 and the ILD 116 and vertical side surfaces of the first encapsulation layer 124. The conductive material layer may include materials such as, for example, tungsten nitride (WN), titanium nitride (TiN) tantalum (Ta), ruthenium (Ru), titanium (Ti), tungsten (W), molybdenum (Mo), platinum (Pt). The conductive material layer may be deposited using typical deposition techniques, for example, physical vapor deposition, atomic layer deposition, molecular layer deposition, and chemical vapor deposition. A planarization process, such as, for example, chemical mechanical polishing (CMP), may be done to remove excess material from a top surface of the structure 100 such that upper horizontal surfaces of the bottom electrode pillar 126, the first encapsulation layer 124 and the ILD 116 are coplanar.

In an embodiment, the bottom electrode pillar 126 may have a thickness ranging from about 10 nm to about 100 nm, although a thickness less than 10 nm and greater than 100 nm may be acceptable.

The bottom electrode includes the bottom electrode pad 114 and the bottom electrode pillar 126.

A planarization process, such as, for example, chemical mechanical polishing (CMP), may be done to remove excess material from a top surface of the structure 100 such that upper horizontal surfaces of the ILD 116, the bottom electrode pillar 126 and the first encapsulation layer 124 are coplanar.

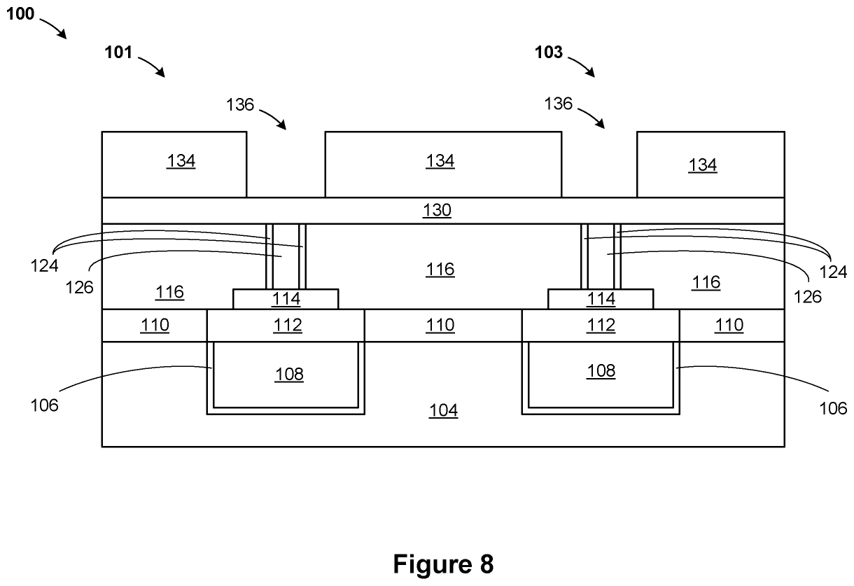

Referring now to FIG. 8, a cross-sectional view of the structure 100 is shown, according to an embodiment. An inter-layer dielectric (hereinafter “ILD”) 130 may be formed. A hard mask 134 may be formed and patterned.

The ILD 130 may be formed as described for the ILD 104, conformally on the structure 100, covering upper horizontal surfaces of the first encapsulation layer 124, the bottom electrode pillar 126 and the ILD 116. The ILD 130 is unlikely to contain voids as the ILD 130 is blanket deposited on the structure 100. This is less likely to contain voids than forming an inter-layer dielectric surrounding multiple layers of the cell 101, 103.

A planarization process, such as, for example, chemical mechanical polishing (CMP), may be done to remove excess material from a top surface of the structure 100 such that an upper horizontal surface of the ILD 130 is planar.

The hard mask 134 is formed on the structure 100 and patterned, directly on an upper horizontal surface of the ILD 130. The hard mask 134 may be patterned such that portions of the hard mask 134 are removed, forming an opening 136. The opening 136 may be vertical aligned above the bottom electrode pillar 126, the bottom electrode pad 114, the metal cap 112 and the lower metal wire 108, in each of the cells 101, 103.

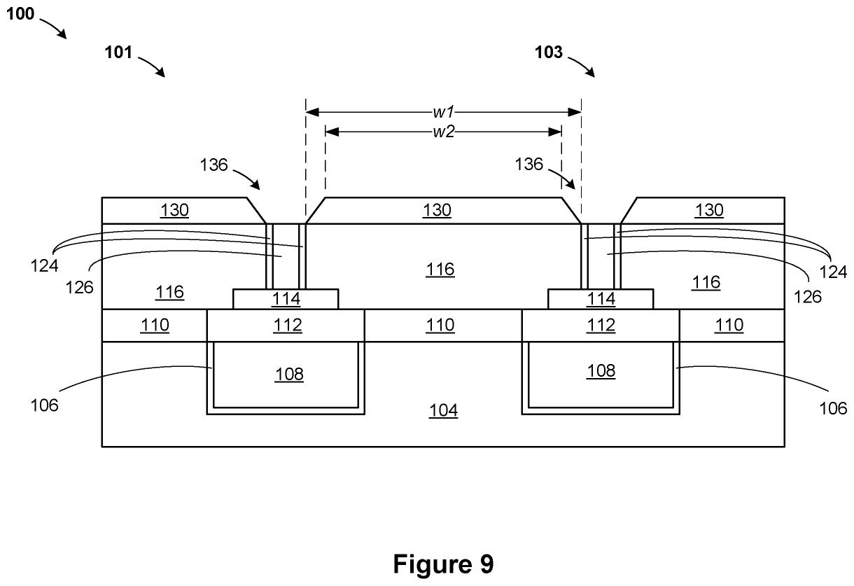

Referring now to FIG. 9, a cross-sectional view of the structure 100 is shown, according to an embodiment. Portions of the ILD 130 may be removed. The hard mask 134 may be removed.

Portions of the ILD 130 may be removed selective to the hard mask 134. The portions of the ILD 130 may be selectively removed using an anisotropic etching technique, such as, for example, reactive ion etching. The ILD 130 may have a tapered side surface, with a width of the ILD 130 at a lower surface closer to the lower metal wire 108, w1, wider than a width at an upper surface of the ILD 130, w2.

The hard mask 134 may be removed using known techniques.

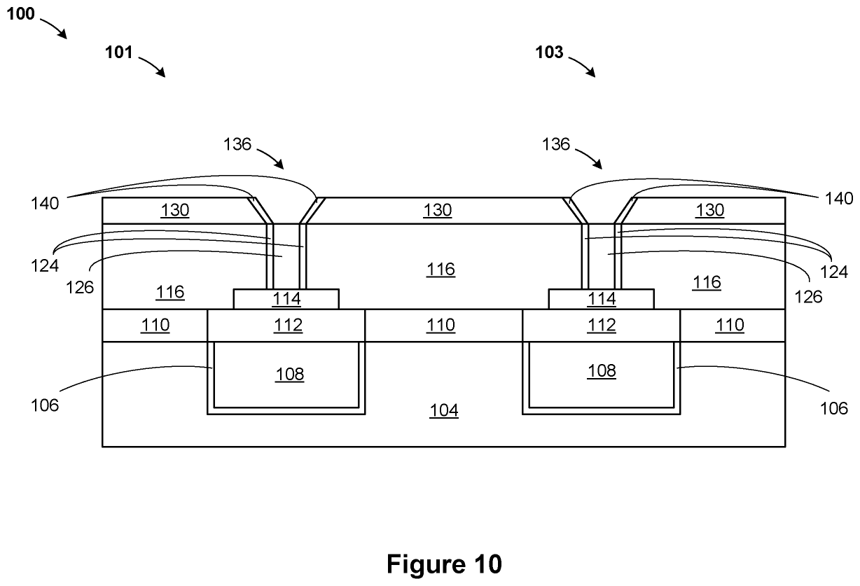

Referring now to FIG. 10, a cross-sectional view of the structure 100 is shown, according to an embodiment. A second encapsulation layer 140 may be formed.

The second encapsulation layer 140 may be conformally formed on the structure 100, on an upper horizontal surface and vertical side surfaces of the ILD 130, on upper horizontal surfaces of the bottom electrode pillar 126 and the first encapsulation layer 123, filling a portion of the opening 136. The second encapsulation layer 140 may be formed as described for the first encapsulation layer 124. The second encapsulation layer 140 may have a thickness between 3 nm and 30 nm, although thickness greater than 30 nm or less than 3 nm are acceptable. The second encapsulation layer 140 helps to protect a subsequently formed reference layer from being damaged or oxidized during subsequent ILD materials deposition.

Portions of the second encapsulation layer 140 may be removed. The portions of the second encapsulation layer 140 may be selectively removed using an anisotropic etching technique, such as, for example, reactive ion etching. The remaining portions of the second encapsulation layer 140 may remain vertically aligned directly adjacent to the ILD 130, in both the cells 101, 103. The second encapsulation layer 140 may be removed from upper horizontal surfaces of the bottom electrode pillar 126 and the ILD 130.

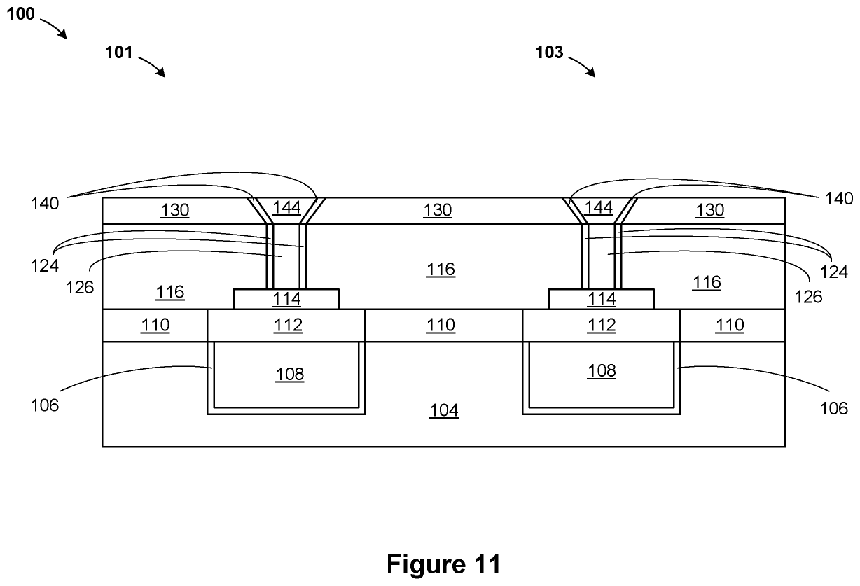

Referring now to FIG. 11, a cross-sectional view of the structure 100 is shown, according to an embodiment. A reference layer 144 may be formed.

The reference layer 144 may be formed conformally on the structure 100. The reference layer 144 may cover upper horizontal surfaces of the ILD 130, the second encapsulation layer 140 and the bottom electrode pillar 126.

Portions of the reference layer 144 may be removed using an anisotropic etching technique, such as, for example, reactive ion etching. The remaining portions of the reference layer 144 may remain vertically aligned above the bottom electrode pillar 126, the bottom electrode pad 114, the metal cap 112 and the lower metal wire 108, in both the cells 101, 103.

A planarization process, such as, for example, chemical mechanical polishing (CMP), may be done to remove excess material from a top surface of the structure 100 such that upper horizontal surfaces of the ILD 130, the reference layer 144 and the second encapsulation layer 140 are coplanar.

The reference layer 144 may have a tapered side surface, with a width of the reference layer 144 at a lower surface closer to the lower metal wire 108, smaller than a width at an upper surface of the reference layer 144.

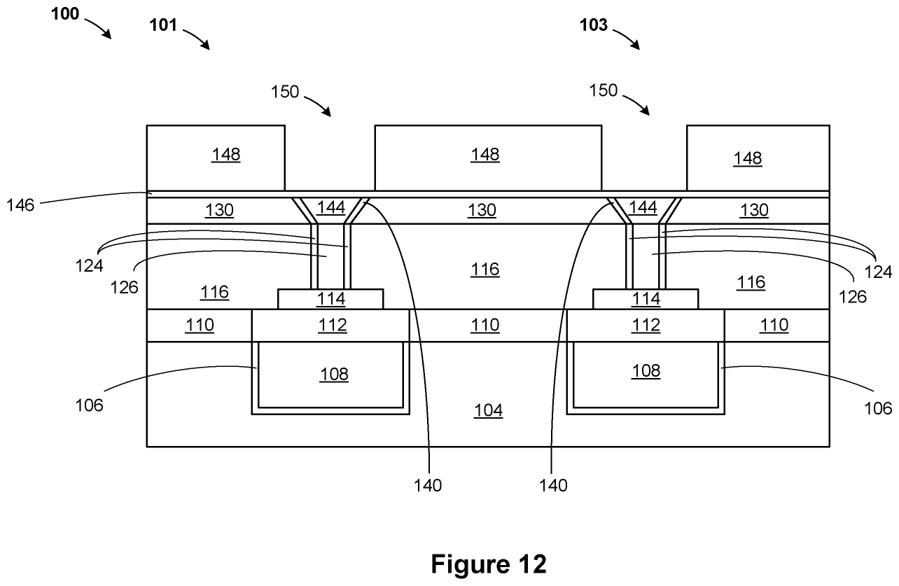

Referring now to FIG. 12, a cross-sectional view of the structure 100 is shown, according to an embodiment. An inter-layer dielectric (hereinafter “ILD”) 146 and a hard mask 148 may be formed.

The ILD 146 may be formed as described for the ILD 104, directly on upper horizontal surfaces of the reference layer 144, the second encapsulation layer 140 and the ILD 130. The ILD 146 is unlikely to contain voids as the ILD 146 is blanket deposited on the planarized upper surfaces of the reference layer 144, the second encapsulation layer 140 and the ILD 130. This is less likely to contain voids than forming an inter-layer dielectric surrounding multiple layers of the cell 101, 103.

A planarization process, such as, for example, chemical mechanical polishing (CMP), may be done to remove excess material from a top surface of the structure 100 such that an upper horizontal surfaces of the ILD 146 is planar.

The hard mask 148 is formed on the structure 100 and patterned, directly on an upper horizontal surface of the ILD 146. The hard mask 148 may be patterned such that portions of the hard mask 148 are removed, forming an opening 150. The opening 150 may be vertical aligned above the reference layer 144, the bottom electrode pad 114, the metal cap 112 and the lower metal wire 108, in each of the cells 101, 103.

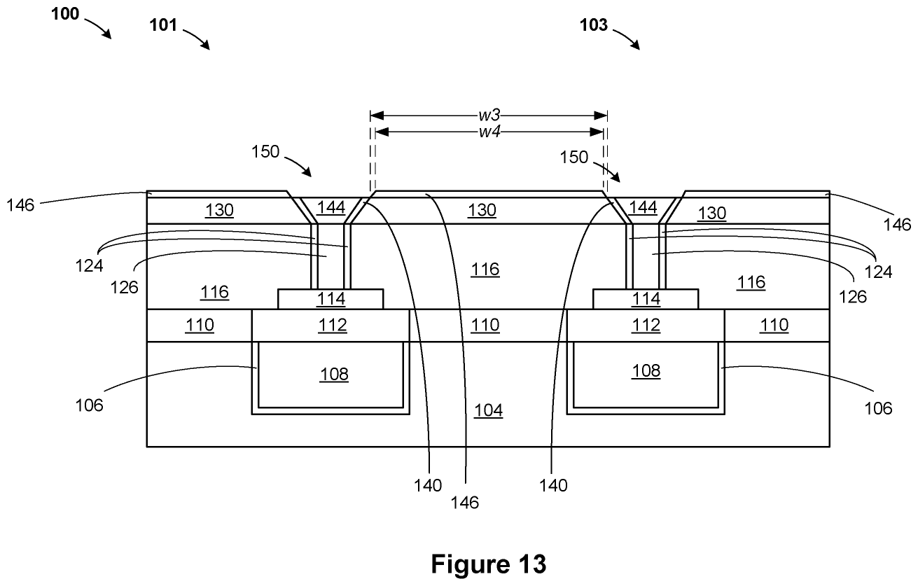

Referring now to FIG. 13, a cross-sectional view of the structure 100 is shown, according to an embodiment. Portions of the ILD 146 may be removed. The hard mask 148 may be removed.

The portions of the ILD 146 may be removed exposing an upper surface of the reference layer 144. The portions of the ILD 146 may be selectively removed using an anisotropic etching technique, such as, for example, reactive ion etching, extending the openings 120. The ILD 146 may have a tapered side surface, with a width of the ILD 146 at a lower surface closer to the lower metal wire 108, w3, wider than a width at an upper surface of the ILD 146, w4.

The hard mask 148 may be removed using known techniques.

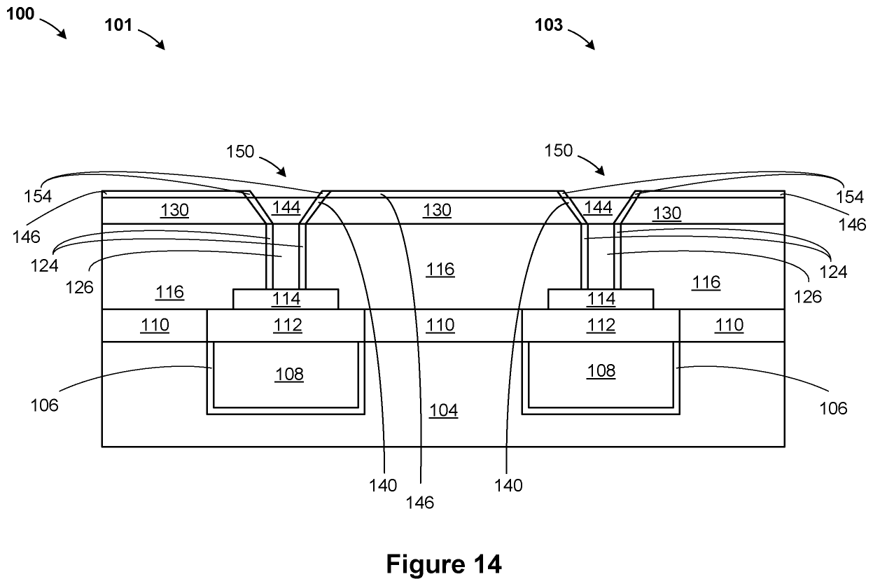

Referring now to FIG. 14, a cross-sectional view of the structure 100 is shown, according to an embodiment. A third encapsulation layer 154 may be formed.

The third encapsulation layer 154 may be conformally formed on the structure 100, on an upper horizontal surface of the ILD 146, and on an upper horizontal surface of the reference layer 144, filling a portion of the opening 150. The third encapsulation layer 154 may be formed as described for the first encapsulation layer 124. The third encapsulation layer 154 helps to protect a subsequently formed tunneling barrier from being damaged or oxidized during subsequent ILD materials deposition.

Portions of third encapsulation layer 154 may be removed. The portions of the third encapsulation layer 154 may be selectively removed using an anisotropic etching technique, such as, for example, reactive ion etching. The remaining portions of the third encapsulation layer 154 may remain vertically aligned directly adjacent to the ILD 146, in both the cells 101, 103. The third encapsulation layer 154 may be removed from upper horizontal surfaces of the reference layer 144 and the ILD 146.

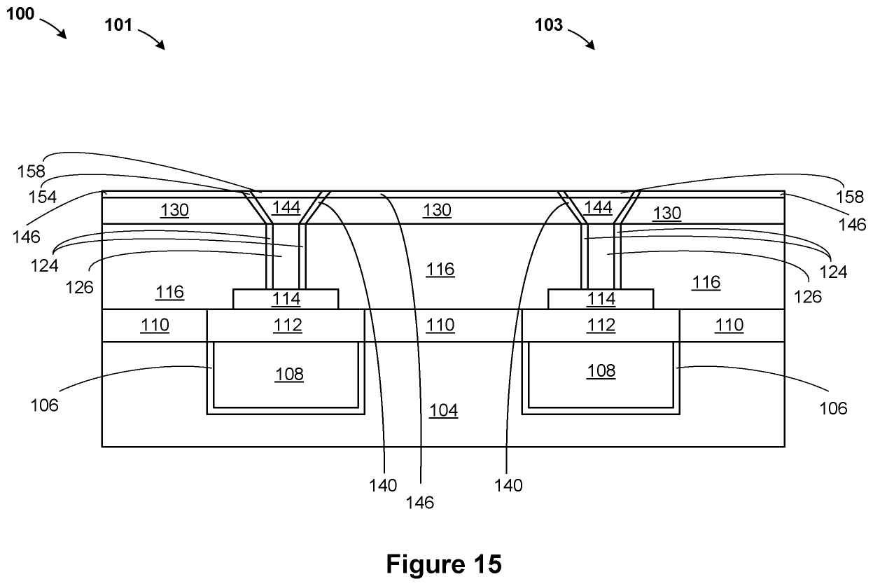

Referring now to FIG. 15, a cross-sectional view of the structure 100 is shown, according to an embodiment. A tunneling barrier 158 may be formed.

The tunneling barrier 158 may be formed conformally on the structure 100, on an upper horizontal surfaces of the ILD 146, the reference layer 144 and the third encapsulation layer 154.

A planarization process, such as, for example, chemical mechanical polishing (CMP), may be done to remove excess material from a top surface of the structure 100 such that upper horizontal surfaces of the ILD 146, the tunneling barrier 158 and the third encapsulation layer 154 are coplanar.

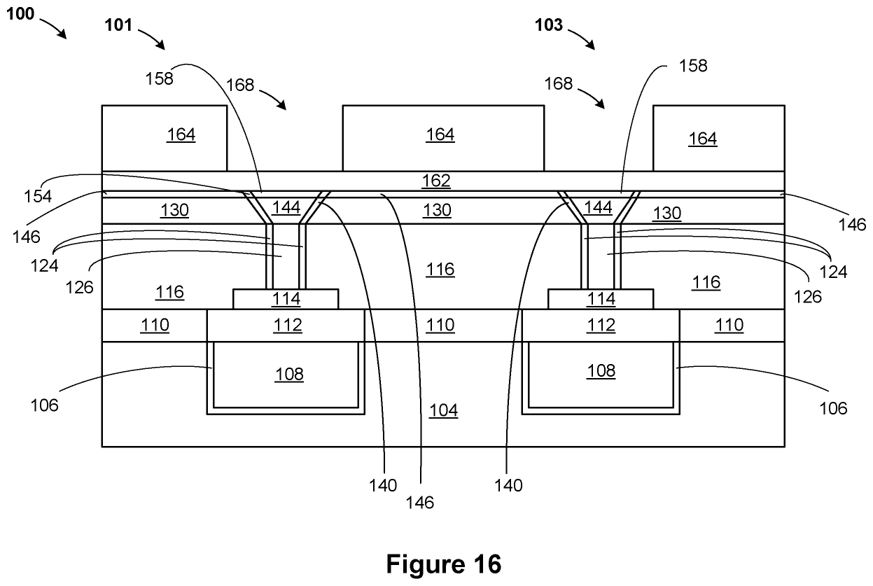

Referring now to FIG. 16, a cross-sectional view of the structure 100 is shown, according to an embodiment. An inter-layer dielectric (hereinafter “ILD”) 162 may be formed. A hard mask 164 is formed and patterned.

The ILD 162 may be formed as described for the ILD 104, conformally on the structure 100, covering upper horizontal surfaces of the third encapsulation layer 154, the tunneling barrier 158 and the ILD 130. The ILD 162 is unlikely to contain voids as the ILD 162 is blanket deposited on the structure 100. This is less likely to contain voids than forming an inter-layer dielectric surrounding multiple layers of the cell 101, 103.

A planarization process, such as, for example, chemical mechanical polishing (CMP), may be done to remove excess material from a top surface of the structure 100 such that an upper horizontal surface of the ILD 162 is planar.

The hard mask 164 is formed on the structure 100 and patterned, directly on an upper horizontal surface of the ILD 162. The hard mask 164 is patterned such that portions of the hard mask 164 are removed, forming an opening 168. The opening 168 is vertically aligned above the tunneling barrier 158, the reference layer 144, the bottom electrode pillar 126, the bottom electrode pad 114, the metal cap 112 and the lower metal wire 108, in each of the cells 101, 103.

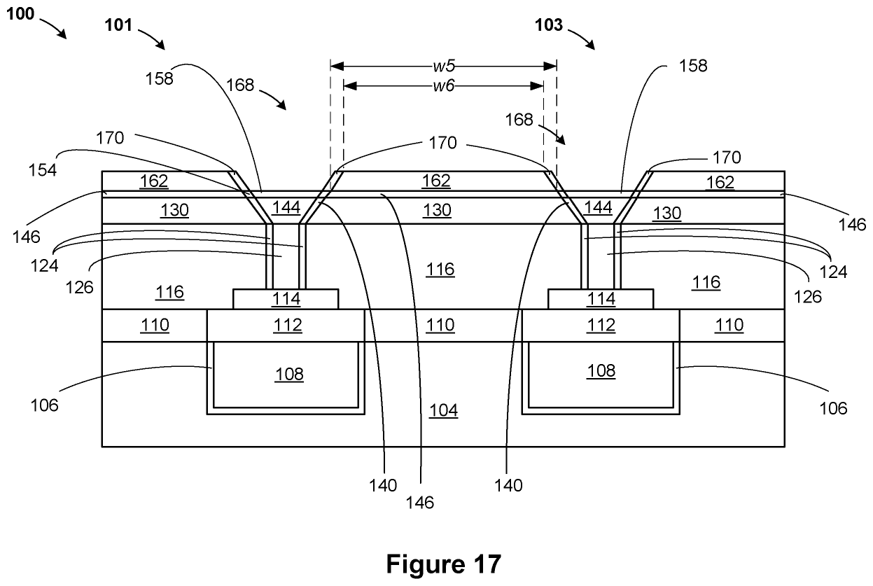

Referring now to FIG. 17, a cross-sectional view of the structure 100 is shown, according to an embodiment. Portions of the ILD 162 may be removed. The hard mask 164 may be removed. A fourth encapsulation layer 170 may be formed.

Portions of the ILD 162 may be removed selective to the hard mask 164. The portions of the ILD 162 may be selectively removed using an anisotropic etching technique, such as, for example, reactive ion etching. The ILD 162 may have a tapered side surface, with a width of the ILD 162 at a lower surface closer to the lower metal wire 108, w5, wider than a width at an upper surface of the ILD 162, w6.

The hard mask 164 may be removed using known techniques.

The fourth encapsulation layer 170 may be conformally formed on the structure 100, on an upper horizontal surface and vertical side surfaces of the ILD 162, on upper horizontal surfaces of the tunneling barrier 158 and the third encapsulation layer 154, filling a portion of the opening 168. The fourth encapsulation layer 170 may be formed as described for the first encapsulation layer 124. The fourth encapsulation layer 170 may have a thickness between 3 nm and 30 nm, although thickness greater than 30 nm or less than 3 nm are acceptable. The fourth encapsulation layer 170 helps to protect a subsequently formed free layer from being damaged or oxidized during subsequent ILD materials deposition.

Portions of the fourth encapsulation layer 170 may be removed. The portions of the fourth encapsulation layer 170 may be selectively removed using an anisotropic etching technique, such as, for example, reactive ion etching. The remaining portions of the fourth encapsulation layer 170 may remain vertically aligned directly adjacent to the ILD 162, in both the cells 101, 103. The fourth encapsulation layer 170 may be removed from upper horizontal surfaces of the tunneling barrier 158 and the ILD 162.

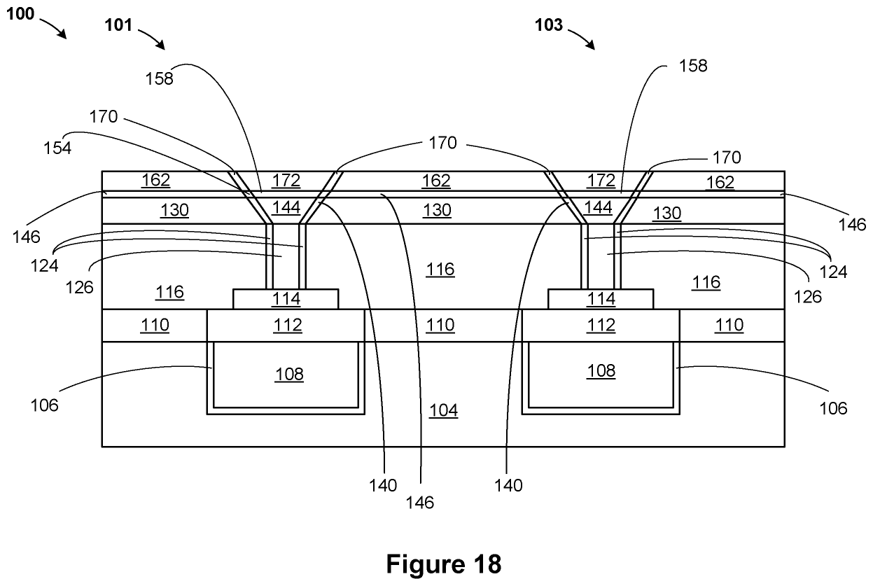

Referring now to FIG. 18, a cross-sectional view of the structure 100 is shown, according to an embodiment. A free layer 172 is formed.

The free layer 172 may be formed conformally on the structure 100, on surfaces of the tunneling barrier 158, the fourth encapsulation layer 170 and the ILD 162, filling remaining portions of the opening 168.

A planarization process, such as, for example, chemical mechanical polishing (CMP), may be done to remove excess material from a top surface of the structure 100 such that upper horizontal surfaces of the free layer 172, the fourth encapsulation layer 170 and the ILD 162 are coplanar.

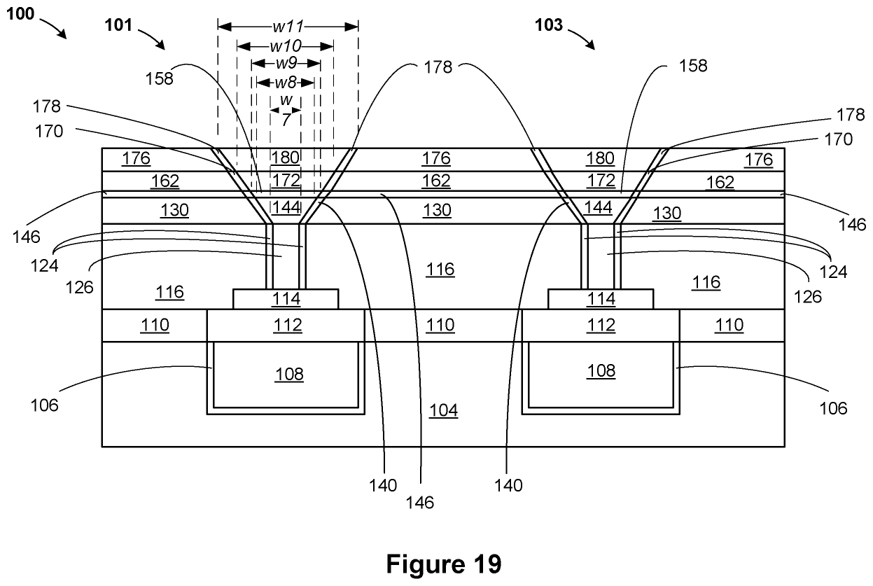

Referring now to FIG. 19, a cross-sectional view of the structure 100 is shown, according to an embodiment. An inter-layer dielectric (hereinafter “ILD”) 176 may be formed. A fifth encapsulation layer 178 may be formed. A top electrode 180 may be formed.

The ILD 176 may be formed as described for the ILD 104, conformally on the structure 100, covering upper horizontal surfaces of the fourth encapsulation layer 170, the free layer 172 and the ILD 162. The ILD 176 is unlikely to contain voids as the ILD 176 is blanket deposited on the structure 100. This is less likely to contain voids than forming an inter-layer dielectric surrounding multiple layers of the cell 101, 103. A planarization process, such as, for example, chemical mechanical polishing (CMP), may be done to remove excess material from a top surface of the structure 100 such that an upper horizontal surface of the ILD 176 is planar.

A hard mask (not shown) may be formed on the structure 100 and patterned, directly on an upper horizontal surface of the ILD 176. The hard mask (not shown) is patterned such that portions of the hard mask (not shown) are removed, forming an opening (not shown) which is vertically aligned above the free layer 172, the tunneling barrier 158, the reference layer 144, the bottom electrode pillar 126, the bottom electrode pad 114, the metal cap 112 and the lower metal wire 108, in each of the cells 101, 103.

Portions of the ILD 176 may be removed selective to the hard mask (not shown). The portions of the ILD 176 may be selectively removed using an anisotropic etching technique, such as, for example, reactive ion etching. The ILD 176 may have a tapered side surface, with a width of the ILD 176 at a lower surface closer to the lower metal wire 108, wider than a width at an upper surface of the ILD 176. The hard mask (not shown) may be removed using known techniques.

The fifth encapsulation layer 178 may be conformally formed on the structure 100, on an upper horizontal surface and vertical side surfaces of the ILD 176, on upper horizontal surfaces of the free layer 172 and the fourth encapsulation layer 170, filling a portion of the opening (not shown). The fifth encapsulation layer 178 may be formed as described for the first encapsulation layer 124. The fifth encapsulation layer 178 may have a thickness between 3 nm and 30 nm, although thickness greater than 30 nm or less than 3 nm are acceptable. The fifth encapsulation layer 178 helps to protect a subsequently formed top electrode from being damaged or oxidized during subsequent ILD materials deposition.

Portions of the fifth encapsulation layer 178 may be removed. The portions of the fifth encapsulation layer 178 may be selectively removed using an anisotropic etching technique, such as, for example, reactive ion etching. The remaining portions of the fifth encapsulation layer 178 may remain vertically aligned directly adjacent to the ILD 176, in both the cells 101, 103. The fifth encapsulation layer 178 may be removed from upper horizontal surfaces of the free layer 172 and the ILD 176.

The top electrode 180 is formed from a conductive material layer which is blanket deposited on top of the structure 100, and directly on a top surface of the free layer 172, the fifth encapsulation layer 178 and the ILD 176. The conductive material layer may include materials such as, for example, tantalum nitride (TaN), tantalum (Ta), titanium (Ti), titanium nitride (TiN). The conductive material layer may be deposited using typical deposition techniques, for example, physical vapor deposition, atomic layer deposition, molecular layer deposition, and chemical vapor deposition.

A planarization process, such as, for example, chemical mechanical polishing (CMP), may be done to remove excess material from a top surface of the structure 100 such that upper horizontal surfaces of the top electrode 180, the fifth encapsulation layer 178 and the ILD 176 are coplanar.

Vertical sidewalls of the top electrode 180, the free layer 172, the tunneling barrier 158 and the reference layer 144 may each have the same sidewall angle, which may range between 10 and 50 degrees in an embodiment.

More specifically, a lower horizontal surface width, as measured from an upper surface of the lower metal wire 108, w7, of the reference layer 144, is less than an upper horizontal surface width, w8, of the reference layer 144. A lower horizontal surface width of the tunneling barrier 158, is the same as the upper horizontal surface width of the reference layer 144, w8. The lower horizontal surface width of the tunneling barrier 158, w8, is less than an upper horizontal surface width of the tunneling barrier 158, w9. A lower horizontal surface width of the free layer 172, is the same as the upper horizontal surface width of the tunneling barrier 158, w9. The lower horizontal surface width of the free layer 172, w9, is less than an upper horizontal surface width of the free layer 172, w10. A lower horizontal surface width of the top electrode 180, is the same as the upper horizontal surface width of the free layer 172, w10. The lower horizontal surface width of the top electrode 180, w10, is less than an upper horizontal surface width of the top electrode 180, w11.

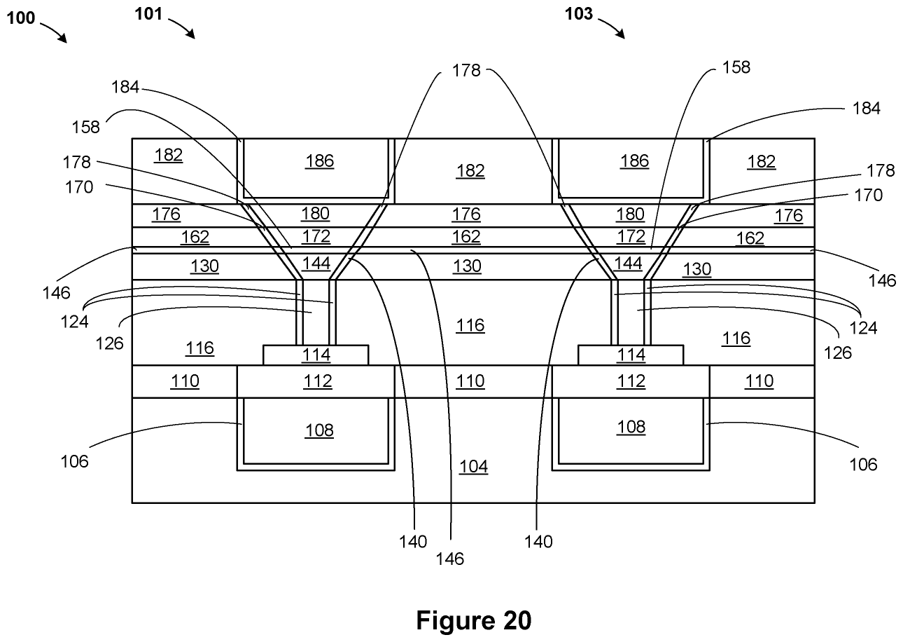

Referring now to FIG. 20, a cross-sectional view of the structure 100 is shown, according to an embodiment. An inter-layer dielectric (hereinafter “ILD”) 172 may be formed. A liner 184 and an upper metal wire 186 may be formed.

The ILD 182 may be formed as described for the ILD 104, on the ILD 176, the top electrode 180 and the fourth encapsulation layer 170. A planarization process, such as, for example, chemical mechanical polishing (CMP), may be done to remove excess material from a top surface of the structure 100 such that an upper horizontal surface of the ILD 182 is planar.

An opening (not shown) may be formed in the ILD 182, exposing the upper horizontal surface of the top electrode 180. The liner 184 and the upper metal wire may be forming in the opening (not shown), and may be formed as described for the lower metal wire 108 and the liner 106. A planarization process, such as, for example, chemical mechanical polishing (CMP), may be done to remove excess material from a top surface of the structure 100 such that upper horizontal surfaces of the ILD 182, the liner 184 and the upper metal wire 186 are coplanar.

The structure 100 has vertically aligned portions of the MTJ stack, including the bottom electrode pillar 126, the bottom electrode pad 114, the reference layer 144, the tunneling barrier 158, the free layer 172 and the top electrode 180. Each of these layers are individually formed with an individually or separately formed ILD layer surrounding them.

The individually or separately formed layers include the following. Vertical side surfaces of the bottom electrode pillar 126 are surrounded by the first encapsulation layer 124. Vertical side surfaces of the first encapsulation layer 124 surrounding the bottom electrode pillar 126 and vertical side surfaces and an upper surface of the bottom electrode pad 114 are surrounded by the ILD 116. Vertical side surface of the reference layer 144 are surrounding by the second encapsulation layer 140. Vertical side surfaces of the second encapsulation layer 140 are surrounded by the ILD 130. Vertical side surface of the tunneling barrier 158 are surrounding by the third encapsulation layer 154. Vertical side surfaces of the third encapsulation layer 154 are surrounded by the ILD 146. Vertical side surface of free layer 172 are surrounding by the fourth encapsulation layer 170. Vertical side surfaces of the fourth encapsulation layer 170 are surrounded by the ILD 162. Vertical side surface of the top electrode 180 are surrounding by the fifth encapsulation layer 178. Vertical side surfaces of the fifth encapsulation layer 178 are surrounded by the ILD 176.

The MTJ stack is vertically aligned between the lower metal wire 108 and the upper metal wire 186. The vertical side surfaces of the reference layer 144, the tunneling barrier 158, the free layer 172 and the top electrode 180 have each been individually formed with a tapered side surface wider at an upper surface. The vertical side surfaces of the bottom electrode pillar 126, the reference layer 144, the tunneling barrier 158, the free layer 172 and the top electrode 180 are each surrounded by a encapsulation layer.

An MRAM pillar having a tapered side surface wider at an upper surface, with an individually formed ILD surrounding each layer, and a multi-level bottom electrode, helps to reduce ILD voiding between adjacent MTJ stacks. This helps to extend scalability of MRAM device memory elements due to void-free gap fill between MRAM pillars and improved embedded MRAM performance due to reduced top contact shorts.

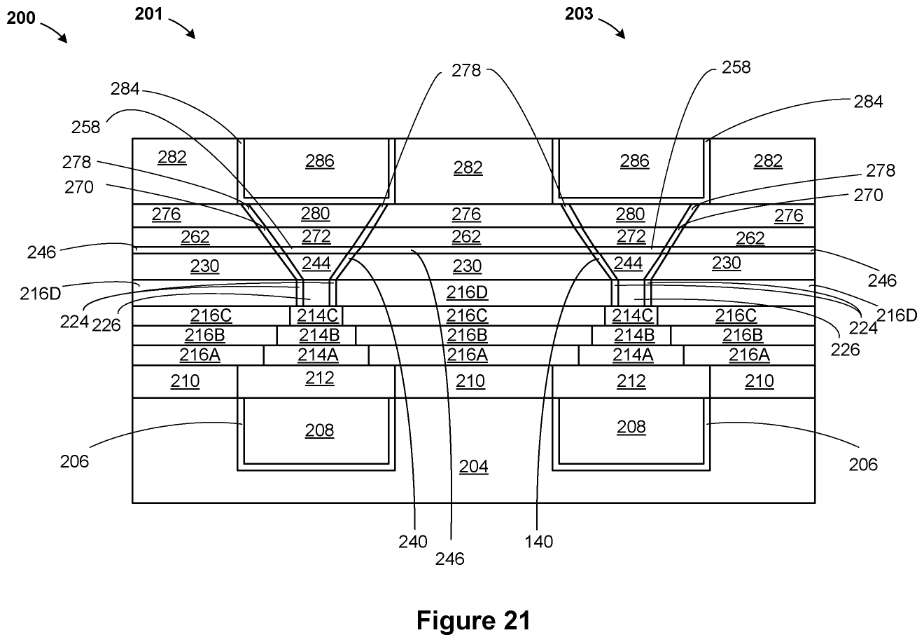

Referring now to FIG. 21, a cross-sectional view of a structure 200 is shown, according to an embodiment. The structure 200 includes cells 201 and 203. Each cell 201, 203 includes an inter-layer dielectric (hereinafter “ILD”) 204, a liner 206, a lower metal wire 108, dielectric cap 210, a metal cap 212, a bottom electrode pad 214A, an inter-layer dielectric (hereinafter “ILD”) 216A, a bottom electrode pad 214B, an inter-layer dielectric (hereinafter “ILD”) 216B, a bottom electrode pad 214C, an inter-layer dielectric (hereinafter “ILD”) 216C, an inter-layer dielectric (hereinafter “ILD”) 216D, a first encapsulation layer 224, a bottom electrode pillar 226, an inter-layer dielectric (hereinafter “ILD”) 230, a second encapsulation layer 240, a reference layer 244, an inter-layer dielectric (hereinafter “ILD”) 246, a third encapsulation layer 254, a tunneling barrier 258, an inter-layer dielectric (hereinafter “ILD”) 262, a fourth encapsulation layer 270, a free layer 272, an inter-layer dielectric (hereinafter “ILD”) 276, a fifth encapsulation layer 278, a top electrode 280, an inter-layer dielectric (hereinafter “ILD”) 282, a liner 284 and an upper metal wire 286.

All elements of the structure 200 are formed as described for the structure 100 for elements of similar names.

Differences between the structure 100 and the structure 200 include additional bottom electrode pads and additional inter-layer dielectric (hereinafter “ILD”) layers.

The bottom electrode pads 214A, 214B, 214C may each be formed as described for the bottom electrode pad 114. The bottom electrode pad 214A may be formed, then the ILD 216A may be formed, then the bottom electrode pad 214B may be formed, then the ILD 216B may be formed, then the bottom electrode pad 214C may be formed, then the ILD 216C may be formed. Next the ILD 216D may be formed, the first encapsulation layer 224 may be formed and the bottom electrode pillar 226 may be formed.

The bottom electrode includes the bottom electrode pads 214A, 214B, 214C and the bottom electrode pillar 226. In an embodiment, there may be any number of bottom electrode pads 214A, 214B, 214C between the bottom electrode pillar 226 and the lower metal wire 208.

The positioning of the lower metal wire 208 and the upper metal wire 286 has a fixed spacing or height between them, and the MRAM device of each cell 101, 103 are formed within this spacing.

The structure 200 has vertically aligned portions of the MTJ stack, including the bottom electrode pillar 226, the bottom electrode pads 214A, 214B, 214C, the reference layer 244, the tunneling barrier 258, the free layer 272 and the top electrode 280. Each of these layers are individually formed with an individually formed ILD layer surrounding them. The MTJ stack is vertically aligned between the lower metal wire 208 and the upper metal wire 286 The vertical side surfaces of the reference layer 244, the tunneling barrier 258, the free layer 272 and the top electrode 280 have each been individually formed with a tapered side surface wider at an upper surface. The vertical side surfaces of the bottom electrode pillar 236, the reference layer 244, the tunneling barrier 258, the free layer 272 and the top electrode 280 are each surrounded by a encapsulation layer.

An MRAM pillar having a tapered side surface wider at an upper surface, with individually formed ILD surrounding each layer, and a multi-level bottom electrode, helps to reduce ILD voiding between adjacent MTJ stacks. This helps to extend scalability of MRAM device memory elements due to void-free gap fill between MRAM pillars and improved embedded MRAM performance due to reduced top contact shorts.

According to an embodiment of the present invention, a semiconductor device is provided. The semiconductor device including a magnetic tunnel junction (MTJ) stack having a bottom electrode, where the bottom electrode includes a first bottom electrode pad and a bottom electrode pillar.

An embodiment where the first bottom electrode pad includes a width greater than a height of the first bottom electrode pad, and the bottom electrode pillar includes a height greater than a width of the bottom electrode pillar. An embodiment where the MTJ stack includes a top electrode above a free layer, the free layer above a tunneling barrier, the tunneling barrier above a reference layer, the reference layer above the bottom electrode pillar, where the top electrode, the free layer, the tunneling barrier and the reference layer each include a tapered side surface of the same angle, where the top electrode, the free layer, the tunneling barrier and the reference layer each have a width at an upper surface greater than a width at a lower surface. An embodiment further including separately formed inter-layer dielectric layers surrounding vertical side surfaces of each of the top electrode, the free layer, the tunneling barrier, the reference layer, the first bottom electrode pad and the bottom electrode pillar. An embodiment further including separately formed encapsulation layers surrounding vertical side surfaces of each of the bottom electrode pillar, the reference layer, the tunneling barrier, and the top electrode. An embodiment where the separately formed encapsulation layers each include hafnium oxide (HfO2). An embodiment where the bottom electrode includes tungsten nitride. An embodiment where the bottom electrode further includes a second bottom electrode pad above the first bottom electrode pad and below the bottom electrode pillar, where the first bottom electrode pad, the second bottom electrode pad and the bottom electrode pillar each includes a vertical side surface substantially perpendicular to an upper surface of a metal word line below and electrically connected to the bottom electrode.

According to an embodiment of the present invention, a magnetic tunnel junction stack is provided, the magnetic junction stack including vertically aligned layers of a top electrode, a free layer, a tunneling barrier, a reference layer and a bottom electrode, where the top electrode includes a tapered side surface having a width at an upper surface of the top electrode greater than a width at a lower surface of the top electrode, and the bottom electrode includes a first bottom electrode pad and a bottom electrode pillar.

An embodiment where the first bottom electrode pad has a width greater than a height of the first bottom electrode pad, and the bottom electrode pillar has a height greater than a width of the bottom electrode pillar. An embodiment where the bottom electrode further includes a second bottom electrode pad above the first bottom electrode pad and below the bottom electrode pillar, where the first bottom electrode pad, the second bottom electrode pad and the bottom electrode pillar each include a vertical side surface substantially perpendicular to an upper surface of a metal word line below and electrically connected to the bottom electrode. An embodiment further including the reference layer has a width at an upper surface greater than a width at a lower surface, the tunneling barrier has a width at an upper surface greater than a width at a lower surface, and the reference layer has a width at an upper surface greater than a width at a lower surface. An embodiment further including a first encapsulation layer surrounding vertical side surfaces of the bottom electrode pillar, a second encapsulation layer surrounding vertical side surfaces of a reference layer, a third encapsulation layer surrounding vertical side surfaces of a tunneling barrier, a fourth encapsulation layer surrounding vertical side surfaces of the free layer, and a fifth encapsulation layer surrounding vertical side surfaces of a top electrode. An embodiment further including a first inter-layer dielectric surrounding vertical side surfaces of the bottom electrode pad, a second inter-layer dielectric surrounding vertical side surfaces of the bottom electrode pillar, a third inter-layer dielectric layer surrounding vertical side surfaces of a reference layer, a fourth inter-layer dielectric layer surrounding vertical side surfaces of a tunneling barrier, a fifth inter-layer dielectric layer surrounding vertical side surfaces of the free layer, and a sixth inter-layer dielectric layer surrounding vertical side surfaces of a top electrode. An embodiment where the first encapsulation layer, the second encapsulation layer, the third encapsulation layer, the fourth encapsulation layer and the fifth encapsulation layer each include hafnium oxide (HfO2). An embodiment where the bottom electrode includes tungsten nitride.

According to an embodiment of the present invention, a semiconductor device is provided. The semiconductor device including a magnetic tunnel junction (MTJ) stack, the MTJ stack having a bottom electrode, where the bottom electrode includes a bottom electrode pillar on a first bottom electrode pad on a second bottom electrode pad on a third bottom electrode pad, where the first bottom electrode pad has a first width smaller than a second width of the second bottom electrode pad, which is smaller than a third width of the third bottom electrode pad, where the first bottom electrode pad has the first width greater than a first height of the first bottom electrode pad, the second bottom electrode pad has the second width greater than a second height of the second bottom electrode pad, the third bottom electrode pad has the third width greater than a third height of the third bottom electrode pad, and the bottom electrode pillar has a fourth height greater than a fourth width of the bottom electrode pillar, where the MTJ stack includes a top electrode above a free layer, the free layer above a tunneling barrier, the tunneling barrier above a reference layer, the reference layer above the bottom electrode pillar, where the top electrode, the free layer, the tunneling barrier and the reference layer each include a tapered side surface of the same angle, where the top electrode, the free layer, the tunneling barrier and the reference layer each include a width at an upper surface greater than a width at a lower surface.

An embodiment where the bottom electrode includes tungsten nitride. An embodiment further including separately formed encapsulation layers surrounding vertical side surfaces of each of the bottom electrode pillar, the reference layer, the tunneling barrier and the top electrode. An embodiment where the first bottom electrode pad, the second bottom electrode pad and the bottom electrode pillar each include a vertical side surface substantially perpendicular to an upper surface of a metal word line below and electrically connected to the bottom electrode.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiment, the practical application or technical improvement over technologies found in the marketplace, or to enable others of ordinary skill in the art to understand the embodiments disclosed herein.

What is claimed is:

1. A semiconductor device comprising:
a magnetic tunnel junction (MTJ) stack having a bottom electrode, wherein the bottom electrode comprises a first bottom electrode pad and a bottom electrode pillar.

2. The semiconductor device according to claim 1, wherein the first bottom electrode pad comprises a width greater than a height of the first bottom electrode pad, and the bottom electrode pillar comprises a height greater than a width of the bottom electrode pillar.

3. The semiconductor device according to claim 1, wherein the MTJ stack comprises a top electrode above a free layer, the free layer above a tunneling barrier, the tunneling barrier above a reference layer, the reference layer above the bottom electrode pillar, wherein the top electrode, the free layer, the tunneling barrier and the reference layer each comprise a tapered side surface of the same angle, wherein the top electrode, the free layer, the tunneling barrier and the reference layer each have a width at an upper surface greater than a width at a lower surface.

4. The semiconductor device according to claim 3, further comprising:
separately formed inter-layer dielectric layers surrounding vertical side surfaces of each of the top electrode, the free layer, the tunneling barrier, the reference layer, the first bottom electrode pad and the bottom electrode pillar.

5. The semiconductor device according to claim 3, further comprising:
separately formed encapsulation layers surrounding vertical side surfaces of each of the bottom electrode pillar, the reference layer, the tunneling barrier, and the top electrode.

6. The semiconductor device according to claim 5, wherein the separately formed encapsulation layers each comprise hafnium oxide (HfO2).

7. The semiconductor device according to claim 1, wherein the bottom electrode comprises tungsten nitride.

8. The semiconductor device according to claim 1, wherein the bottom electrode further comprises a second bottom electrode pad above the first bottom electrode pad and below the bottom electrode pillar, wherein the first bottom electrode pad, the second bottom electrode pad and the bottom electrode pillar each comprise a vertical side surface substantially perpendicular to an upper surface of a metal word line below and electrically connected to the bottom electrode.

9. A magnetic tunnel junction stack comprising:
vertically aligned layers of a top electrode, a free layer, a tunneling barrier, a reference layer and a bottom electrode, wherein the top electrode comprises a tapered side surface having a width at an upper surface of the top electrode greater than a width at a lower surface of the top electrode, and the bottom electrode comprises a first bottom electrode pad and a bottom electrode pillar.

10. The magnetic tunnel junction stack according to claim 9, wherein the first bottom electrode pad has a width greater than a height of the first bottom electrode pad, and the bottom electrode pillar has a height greater than a width of the bottom electrode pillar.

11. The magnetic tunnel junction stack according to claim 9, wherein the bottom electrode further comprises a second bottom electrode pad above the first bottom electrode pad and below the bottom electrode pillar, wherein the first bottom electrode pad, the second bottom electrode pad and the bottom electrode pillar each comprise a vertical side surface substantially perpendicular to an upper surface of a metal word line below and electrically connected to the bottom electrode.

12. The magnetic tunnel junction stack according to claim 9, further comprising:
the reference layer has a width at an upper surface greater than a width at a lower surface;
the tunneling barrier has a width at an upper surface greater than a width at a lower surface; and
the reference layer has a width at an upper surface greater than a width at a lower surface.

13. The magnetic tunnel junction stack according to claim 9, further comprising:
a first encapsulation layer surrounding vertical side surfaces of the bottom electrode pillar;
a second encapsulation layer surrounding vertical side surfaces of a reference layer;
a third encapsulation layer surrounding vertical side surfaces of a tunneling barrier;
a fourth encapsulation layer surrounding vertical side surfaces of the free layer; and
a fifth encapsulation layer surrounding vertical side surfaces of a top electrode.

14. The magnetic tunnel junction stack according to claim 9, further comprising:
a first inter-layer dielectric surrounding vertical side surfaces of the bottom electrode pad;
a second inter-layer dielectric surrounding vertical side surfaces of the bottom electrode pillar;
a third inter-layer dielectric layer surrounding vertical side surfaces of a reference layer;
a fourth inter-layer dielectric layer surrounding vertical side surfaces of a tunneling barrier;
a fifth inter-layer dielectric layer surrounding vertical side surfaces of the free layer; and
a sixth inter-layer dielectric layer surrounding vertical side surfaces of a top electrode.

15. The magnetic tunnel junction stack according to claim 13, wherein the first encapsulation layer, the second encapsulation layer, the third encapsulation layer, the fourth encapsulation layer and the fifth encapsulation layer each comprise hafnium oxide (HfO2).

16. The magnetic tunnel junction stack according to claim 9, wherein the bottom electrode comprises tungsten nitride.

17. A semiconductor device comprising:
a magnetic tunnel junction (MTJ) stack, the MTJ stack having a bottom electrode, wherein the bottom electrode comprises a bottom electrode pillar on a first bottom electrode pad on a second bottom electrode pad on a third bottom electrode pad, wherein the first bottom electrode pad has a first width smaller than a second width of the second bottom electrode pad, which is smaller than a third width of the third bottom electrode pad, wherein the first bottom electrode pad has the first width greater than a first height of the first bottom electrode pad, the second bottom electrode pad has the second width greater than a second height of the second bottom electrode pad, the third bottom electrode pad has the third width greater than a third height of the third bottom electrode pad, and the bottom electrode pillar has a fourth height greater than a fourth width of the bottom electrode pillar,
wherein the MTJ stack comprises a top electrode above a free layer, the free layer above a tunneling barrier, the tunneling barrier above a reference layer, the reference layer above the bottom electrode pillar, wherein the top electrode, the free layer, the tunneling barrier and the reference layer each comprise a tapered side surface of the same angle, wherein the top electrode, the free layer, the tunneling barrier and the reference layer each comprise a width at an upper surface greater than a width at a lower surface.

18. The semiconductor device according to claim 17, wherein the bottom electrode comprises tungsten nitride.

19. The semiconductor device according to claim 17, further comprising:
separately formed encapsulation layers surrounding vertical side surfaces of each of the bottom electrode pillar, the reference layer, the tunneling barrier and the top electrode.

20. The semiconductor device according to claim 5, wherein the first bottom electrode pad, the second bottom electrode pad and the bottom electrode pillar each comprise a vertical side surface substantially perpendicular to an upper surface of a metal word line below and electrically connected to the bottom electrode.
